(19) United States
(12) Patent Application Publication
(10) Pub. No.: US 2012/0319295 A1
(43) Pub. Date: Dec. 20, 2012

(54) INTEGRATED CIRCUIT PACKAGING SYSTEM WITH PADS AND METHOD OF MANUFACTURE THEREOF

(76) Inventors: HeeJo Chi, Ichon-si (KR); NamJu Cho, Uiwang-si (KR); HanGil Shin, Seongnam-si (KR)

(21) Appl. No.: 13/163,523

(22) Filed: Jun. 17, 2011

(51) Int. Cl. H01L 23/538; H01L 21/56

(52) U.S. Cl. 257/774; 438/127; 257/E21.502; 257/E23.174

(57) ABSTRACT

A method of manufacture of an integrated circuit packaging system includes: forming a circuit structure having a circuit active side and a cavity from the circuit active side; mounting an integrated circuit device in the cavity; forming a base encapsulation, having a base first side facing away from the circuit active side, on the circuit active side, around the integrated circuit device, and in the cavity; forming a first conductive pin, having a first pin height, in the base encapsulation and traversing from the circuit active side to the base first side; forming a second conductive pin, having a second pin height equivalent to the first pin height, in the base encapsulation and traversing from the integrated circuit device to the base first side; and removing a portion of the circuit structure to form a circuit non-active side and expose the integrated circuit device and a base second side.

### TECHNICAL FIELD

The present invention relates generally to an integrated circuit packaging system, and more particularly to an integrated circuit packaging system with interconnects.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made using the semiconductor package structures. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Many conventional semiconductor (or “chip”) packages are of the type where a semiconductor die is molded into a package with a resin, such as an epoxy molding compound. Numerous package approaches stack multiple integrated circuit dice or package in package (PIP) or a combination. Other approaches include package level stacking or package-on-package (POP). POP designs face reliability challenges and higher cost.

Thus, a need still remains for an integrated circuit system improved yield, low profile, and improved reliability. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: forming a circuit structure having a circuit active side and a cavity from the circuit active side; mounting an integrated circuit device in the cavity; forming a base encapsulation, having a base first side facing away from the circuit active side, on the circuit active side, around the integrated circuit device, and in the cavity; forming a first conductive pin, having a first pin height, in the base encapsulation and traversing from the circuit active side to the base first side; forming a second conductive pin, having a second pin height equivalent to the first pin height, in the base encapsulation and traversing from the integrated circuit device to the base first side; and removing a portion of the circuit structure to form a circuit non-active side and expose the integrated circuit device and a base second side, the base second side opposite the base first side.

The present invention provides an integrated circuit packaging system, including: a circuit structure having a through hole, a circuit active side, and a circuit non-active side with the through hole traversing from the circuit active side to the circuit non-active side; an integrated circuit device in the through hole; a base encapsulation, having a base first side facing away from the circuit active side and a base second side opposite the base first side, on the circuit active side, around the integrated circuit device, and in the through hole; a first conductive pin, having a first pin height, in the base encapsulation and traversing from the circuit active side to the base first side; and a second conductive pin, having a second pin height equivalent to the first pin height, in the base encapsulation and traversing from the integrated circuit device to the base first side.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a top view of the integrated circuit packaging system in a first embodiment of the present invention.

FIG. 2 is a cross-sectional view of the integrated circuit packaging system along line 2-2 of FIG. 1.

FIG. 3 is a bottom view of the integrated circuit packaging system.

FIG. 4 is a cross-sectional view of an integrated circuit packaging system as exemplified by the top view of FIG. 1 along line 2-2 in a second embodiment of the present invention.

FIG. 5 is a cross-sectional view of an integrated circuit packaging system as exemplified by the top view of FIG. 1 along line 2-2 in a third embodiment of the present invention.

FIG. 6 is a cross-sectional view of the integrated circuit packaging system as exemplified by the top view of FIG. 1 along line 2-2 in a fourth embodiment of the present invention.

FIG. 7 is a top view of an integrated circuit packaging system in a fifth embodiment of the present invention.

FIG. 8 is a cross-sectional view of the integrated circuit packaging system along line 8-8 of FIG. 7.

FIG. 9 is a cross-sectional view of an integrated circuit packaging system as exemplified by the top view along line 8-8 of FIG. 7 in a sixth embodiment of the present invention.

FIG. 10 is a top view of an integrated circuit packaging system in a seventh embodiment of the present invention.

FIG. 11 is a cross-sectional view of the integrated circuit packaging system along line 11-11 of FIG. 10.

FIG. 12 is a top view of an integrated circuit packaging system in an eighth embodiment of the present invention.

FIG. 13 is a cross-sectional view of the integrated circuit packaging system along line 13-13 of FIG. 12.

FIG. 14 is a cross-sectional view of a wafer.

FIG. 15 is a cross-sectional view of the structure of FIG. 14 in forming cavities.

FIG. 16 is a cross-sectional view of the structure of FIG. 15 in forming filled channels.

FIG. 17 is a cross-sectional view of the structure of FIG. 16 in mounting the integrated circuit device.

FIG. 18 is a cross-sectional view of the structure of FIG. 17 in forming a wafer encapsulation.

FIG. 19 is a cross-sectional view of the structure of FIG. 18 in forming encapsulation channels.

FIG. 20 is a cross-sectional view of the structure of FIG. 19 in forming the first conductive pins and the second conductive pins.

FIG. 21 is a cross-sectional view of the structure of FIG. 20 in a singulation tape mounting process.

FIG. 22 is a cross-sectional view of the structure of FIG. 21 in a wafer thinning process.

FIG. 23 is a cross-sectional view of the structure of FIG. 22 in a package singulation process for forming the integrated circuit packaging system of FIG. 1.

FIG. 24 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit active side, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements or components with no intervening material.

The term “processing” as used herein includes deposition of material or photoresist, patterning, exposure, development, etching, cleaning, and/or removal of the material or photoresist as required in forming a described structure.

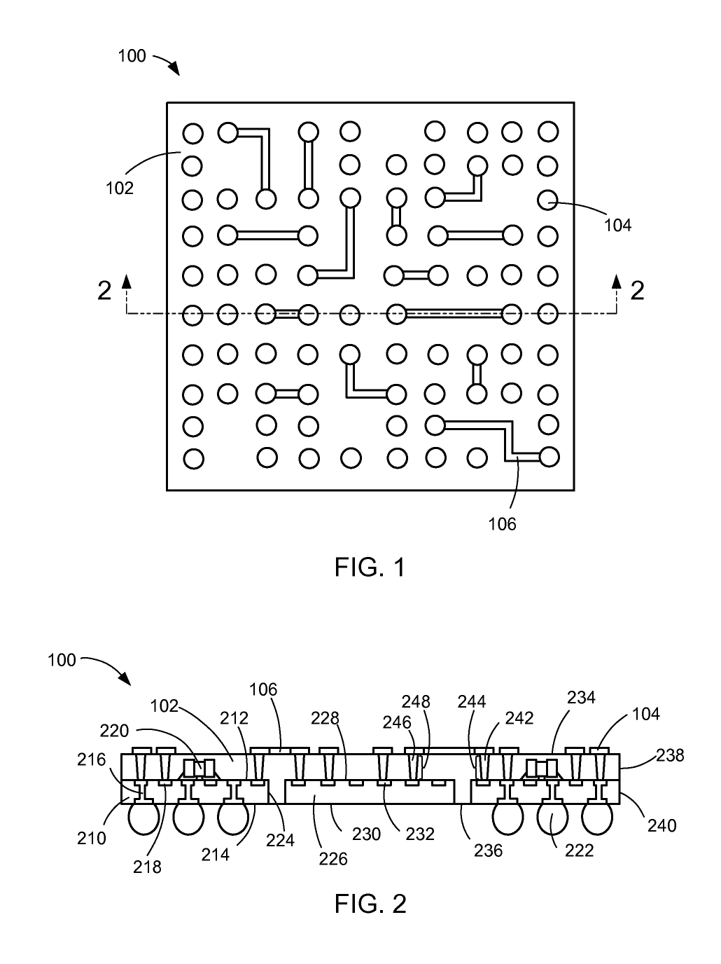

Referring now to FIG. 1, therein is shown a top view of the integrated circuit packaging system 100 in a first embodiment of the present invention. The top view depicts a base encapsulation 102. The base encapsulation 102 is defined as a protective cover that has electric and environmental insulating properties. As an example, the base encapsulation 102 can be formed by molding an encapsulation material such as epoxy molding compound or ceramic material. As a further example, the base encapsulation 102 can have characteristics of being formed by a film assisted molding or injection molding process.

Mount pads 104 can be on the base encapsulation 102. The mount pads 104 are defined as pads for providing electrical interface and connection to components or devices external to packaging system. As an example, the mount pads 104 can be made from a conductive material, such as copper, a copper alloy, gold, a gold alloy, nickel, a nickel alloy, or other alloys. In a further example, the mount pads 104 can be made from at least one layer of a metallic material formed by a plating process. More specifically, the mount pads 104 can be made from a single metallic layer made from plating a single material, multiple metallic layers made from plating a single material, multiple metallic layers made from plating different materials. The mount pads 104 can be at various locations on the base encapsulation 102.

A conductive trace 106 can be on the base encapsulation 102. The conductive trace 106 is defined as a conductive interconnect that is along a surface of a cover for providing electrical connection between pads. As an example, the conductive trace 106 can be made from a conductive material, such as copper, a copper alloy, gold, a gold alloy, nickel, a nickel alloy, or other alloys.

The conductive trace 106 can connect one or more of the mount pads 104. For example, the conductive trace 106 can connect one of the mount pads 104 with another one of the mount pads 104. As a further example, the conductive trace 106 can connect the mount pads 104 that are at various locations on the base encapsulation 102.

Referring now to FIG. 2, therein is shown a cross-sectional view of the integrated circuit packaging system 100 along line 2-2 of FIG. 1. The cross-sectional view depicts a circuit structure 210. The circuit structure 210 is defined as a semiconductor device. As an example, the circuit structure 210 can be an integrated circuit die, a thin integrated circuit die, or a silicon interposer. As a specific example, the circuit structure 210 can be silicon interposer made from a silicon wafer having through silicon vias (TSV).

The circuit structure 210 can have a circuit active side 212 and a circuit non-active side 214. The circuit active side 212 is defined as the side of the circuit structure 210 having active circuitry (not shown) fabricated thereto. The circuit non-active side 214 is defined as the side of the circuit structure 210 opposite the circuit active side 212.

The circuit structure 210 can include conductive vias 216. The conductive vias 216 are defined as channels or holes filled with conductive material that traverse from one surface of a structure to an opposite surface of the structure. The conductive vias 216 can be filled with a conductive material. For example, the conductive vias can be filled with conductive materials such as copper, a copper alloy, gold, a gold alloy, nickel, a nickel alloy, or other alloys.

The conductive vias 216 can be in the circuit structure 210. The conductive vias 216 can traverse through the circuit structure 210 from the circuit active side 212 to the circuit non-active side 214. The conductive vias 216 can be exposed along the circuit active side 212 and the circuit non-active side 214.

Structure pads 218 can be along the circuit active side 212. The structure pads 218 are defined as conductive pads that provide electrical connectivity to an active surface of a device. As an example, the structure pads 218 can be made from a conductive material, such as copper, a copper alloy, gold, a gold alloy, nickel, a nickel alloy, or other alloys. The structure pads 218 can be co-planar with the circuit active side 212. The structure pads 218 can provide electrical connectivity for the active circuitry on the circuit active side 212.

A component device 220 can be on the circuit active side 212. The component device 220 is defined as an electrical component. As an example, the component device 220 can be a device that contains passive components, active components, or circuits formed from the combination thereof. The component device 220 can be connected to the portion of the conductive vias 216 that are exposed along the circuit active side 212, the structure pads 218, or a combination thereof.

External interconnects 222 can be connected to the circuit non-active side 214. The external interconnects 222 are defined as conductive connectors that provide connectivity to other devices and components external to a packaging system. As an example, the external interconnects 222 can be solder balls, solder bumps, or conductive bumps.

The external interconnects 222 can be connected to the portion of the conductive vias 216 that are exposed at the circuit non-active side 214. The external interconnects 222 can connect the integrated circuit packaging system 100 to a next system level down (not shown).

The circuit structure 210 can have a through hole 224. The through hole 224 is defined as an opening or hole that traverses between one surface of a structure to an opposite surface of the structure. The through hole 224 can traverse between the circuit active side 212 and the circuit non-active side 214. The circuit structure 210 can be a single continuous structure with the through hole 224 at an inner portion of the circuit structure 210.

The conductive vias 216 can have a horizontal dimension that is smaller than the horizontal dimension of the through hole 224. The through hole 224 can be sized to fit a device, such as an integrated circuit die.

An integrated circuit device 226 can be in the through hole 224. The integrated circuit device 226 is defined as a semiconductor device. As an example, the integrated circuit device 226 can be an integrated circuit die, a thin integrated circuit die, or an ultrathin integrated circuit die. The through hole 224 can be a space between the vertical side of the circuit structure 210 parallel with and facing the vertical side of the integrated circuit device 226.

The integrated circuit device 226 can have a device active side 228 and a device non-active side 230. The device active side 228 is defined as the side of the integrated circuit device 226 having active circuitry (not shown) fabricated thereon. The device non-active side 230 is defined as the side of the integrated circuit device 226 opposite the device active side 228.

The device active side 228 can be co-planar with the circuit active side 212. The device non-active side 230 can be co-planar with the circuit non-active side 214.

The integrated circuit device 226 can have device pads 232 along the device active side 228. The device pads 232 are defined as conductive pads that provide electrical connectivity to an active surface of a device. As an example, the device pads 232 can be made from a conductive material, such as copper, a copper alloy, gold, a gold alloy, nickel, a nickel alloy, or other alloys. The device pads 232 can be co-planar with the device active side 228. The device pads 232 can provide electrical connectivity for the active circuitry on the device active side 228.

The base encapsulation 102 can be over the circuit structure 210, around the integrated circuit device 226, and in the through hole 224. The base encapsulation 102 can be on the circuit active side 212 and the device active side 228. The base encapsulation 102 can cover the component device 220.

The base encapsulation 102 can have a base first side 234 and a base second side 236. The base encapsulation 102 can be in the through hole 224. The base encapsulation 102 can be in the space between the circuit structure 210 and the integrated circuit device 226. The circuit structure 210 and the integrated circuit device 226 can be exposed from the base encapsulation 102.

The circuit non-active side 214 and the device non-active side 230 can be co-planar with the base second side 236. The circuit non-active side 214, the device non-active side 230, and the base second side 236 can have the characteristics of a surface that is formed as a uniform co-planar surface. A surface formed as uniformly co-planar is defined as a surface that is formed during the same processing or manufacturing step. For example, the circuit non-active side 214, the device non-active side 230, and the base second side 236 can be formed during a single planarization step, such as grinding or polishing. As a further example, the characteristics of a surface that is formed as uniformly co-planar can include continuous and uniform grinding or polishing marks, such as grooves or scratches, across the sides or surfaces of each component or device.

The base encapsulation can have a base lateral side 238. The base lateral side 238 is defined as the vertical side of the base encapsulation 102. A structure lateral side 240 of the circuit structure 210 can be exposed coplanar with the base lateral side 238. The structure lateral side 240 is defined as the vertical side of the circuit structure 210 that is facing away from the through hole 224.

The integrated circuit packaging system 100 can include first conductive pins 242 and second conductive pins 246. The first conductive pins 242 and the second conductive pins 246 are defined as conductive structures in a protective cover that traverses between a side of an active device and a surface of the protective cover. As an example, the first conductive pins 242 and the second conductive pins 246 can be made from conductive material, such as a copper alloy, gold, a gold alloy, nickel, a nickel alloy, or other alloys. The first conductive pins 242 and the second conductive pins 246 can be in and surrounded by the base encapsulation 102.

The first conductive pins 242 can traverse between the circuit active side 212 and the base first side 234. The first conductive pins 242 can be exposed from the base encapsulation 102 at the base first side 234.

The first conductive pins 242 can have a first pin height 244. The first pin height 244 is defined as the measure of length of the first conductive pins 242 from the circuit active side 212 to the base first side 234.

The first conductive pins 242 can be connected to the circuit active side 212. For example, the first conductive pins 242 can be connected to the portion of the conductive vias 216 that are exposed at the circuit active side 212. As a further example, the first conductive pins 242 can be connected to the structure pads 218.

The second conductive pins 246 can traverse between the device active side 228 and the base first side 234. The second conductive pins 246 can be exposed from the base encapsulation 102 at the base first side 234. The exposed portion of the second conductive pins 246 can be co-planar with the base first side 234.

The second conductive pins 246 can have a second pin height 248. The second pin height 248 is defined as the measure of length of the second conductive pins 246 from the device active side 228 to the base first side 234. The second pin height 248 can be equivalent to the first pin height 244. The second pin height 248 equivalent to the first pin height 244 is defined as the distance between the base first side 234 to the circuit active side 212 for the first pin height 244 is the same as the distance between the base first side 234 and the device active side 228 for the second pin height 248.

The second conductive pins 246 can be connected to the device active side 228. For example, the second conductive pins 246 can be connected to the device pads 232.

The first conductive pins 242 and the second conductive pins 246 can have a tapered shape. A tapered shape is defined as a shape having a gradually narrowing width with one end having a greater width than an opposing end. For example, the first conductive pins 242 and the second conductive pins 246 can have a greater width at the end adjacent to the base first side 234 and narrower width at the end adjacent to the circuit active side 212 and the device active side 228, respectively.

The mount pads 104 can be on the base first side 234 of the base encapsulation 102. The mount pads 104 can be connected to the portion of the first conductive pins 242 and the second conductive pins 246 at the base first side 234.

The conductive trace 106 can be on the base first side 234 of the base encapsulation 102. The conductive trace 106 can connect one or more of the mount pads 104. The conductive trace 106 can connect the first conductive pins 242 with the second conductive pins 246. For example, the conductive trace 106 can connect between one of the mount pads 104 connected to one of the first conductive pins 242 and another one of the mount pads 104 connected to one of the second conductive pins 246.

The integrated circuit packaging system 100 can provide an active substrate. The active substrate is defined as a structure, having embedded active devices, that can function as a base for mounting other devices or components. As an example, the integrated circuit packaging system 100 can support components or devices mounted over the base first side. As another example, the integrated circuit packaging system 100 can be inverted and can have components or devices mounted on the circuit non-active side 214, the device non-active side 230, or a combination thereof. As a specific example, the integrated circuit packaging system 100 can be a wafer level chip scale package, which is defined as a packaging system including silicon devices, having circuitry fabricated thereon, fabricated at a wafer level.

It has been discovered that the present invention provides the integrated circuit packaging system 100 with the circuit structure 210, the integrated circuit device 226 and the base encapsulation 102 having a low vertical package profile. The circuit non-active side 214, the device non-active side 230 and the base second side 236 having the characteristics of a uniform co-planar surface enables uniform reduction in package height for the circuit structure 210, the integrated circuit device 226 and the base encapsulation 102, thus providing the integrated circuit packaging system 100 having a low profile.

It has also been discovered that the present invention provides the integrated circuit packaging system 100 with the first conductive pin 242 and the second conductive pin 246 having a low vertical package profile. The second pin height 248 equivalent to the first pin height 244 enables uniform thickness of the portion of the base encapsulation 102 over the circuit structure 210 and the integrated circuit device 226, thus providing the integrated circuit packaging system 100 having a low vertical package profile.

It has further been discovered that the present invention provides the integrated circuit packaging system 100 the first conductive pin 242 and the second conductive pin 246 having reliable connectivity. The first conductive pin 242 and the second conductive pin 246 having the tapered shape having a narrow end that is smaller in width than the structure pads 218 and the device pads 232 enables precise connection with the structure pads 218 and the device pads 232. The precise connection of the first conductive pin 242 and the second conductive pin 246 with the structure pads 218 and the device pads 232 reduces or eliminates the risk of shorting between the structure pads 218 with another of the structure pads 218 or the device pads 232 with another of the device pads 232, thus providing the integrated circuit packaging system having reliable connectivity.

It has yet further been discovered that the present invention provides the integrated circuit packaging system 100 with the circuit structure 210 having, improved performance and integration. The circuit structure 210 having the active circuitry along the circuit active side 212 eliminates the need for additional circuit components and connections between circuit components, thus providing the integrated circuit packaging system 100 with improved performance and integration.

It has yet further been discovered that the present invention provides the integrated circuit packaging system 100 with the circuit structure 210 having a low vertical package profile. The circuit structure 210 having the active circuitry along the circuit active side 212 eliminates the need for additional circuit components or integrated circuits, thus providing the integrated circuit packaging system 100 with a low vertical package profile.

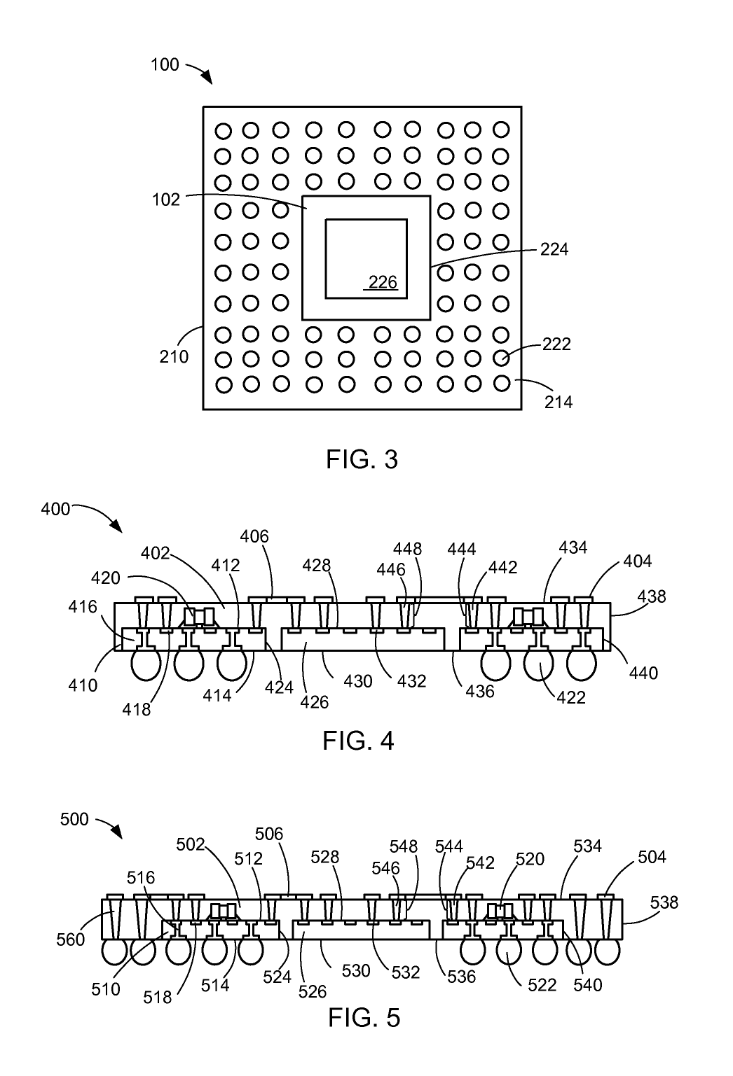

Referring now to FIG. 3, therein is shown a bottom view of the integrated circuit packaging system 100. The bottom view depicts the circuit structure 210 having the through hole 224. The circuit structure 210 can be a single continuous structure with the through hole 224 at an inner portion of the circuit structure 210.

The integrated circuit device 226 can be in the through hole 224. The base encapsulation 102 can be in the through hole 224. The base encapsulation 102 can be in the space between the circuit structure 210 and the integrated circuit device 226. The external interconnects 222 can be along the circuit non-active side 214.

Referring now to FIG. 4, therein is shown a cross-sectional view of an integrated circuit packaging system 400 as exemplified by the top view of FIG. 1 along line 2-2 in a second embodiment of the present invention. The cross-sectional view depicts a circuit structure 410. The circuit structure 410 is defined as a semiconductor device. As an example, the circuit structure 410 can be an integrated circuit die, a thin integrated circuit die, or a silicon interposer. As a specific example, the circuit structure 410 can be silicon interposer made from a silicon wafer having through silicon vias (TSV).

The circuit structure 410 can have a circuit active side 412 and a circuit non-active side 414. The circuit active side 412 is defined as the side of the circuit structure 410 having active circuitry (not shown) fabricated thereto. The circuit non-active side 414 is defined as the side of the circuit structure 410 opposite the circuit active side 412.

The circuit structure 410 can include conductive vias 416. The conductive vias 416 are defined as channels or holes filled with conductive material that traverse from between one surface of a structure to an opposite surface of the structure. The conductive vias 416 can be filled with a conductive material. For example, the conductive vias can be filled with conductive materials such as copper, a copper alloy, gold, a gold alloy, nickel, a nickel alloy, or other alloys.

The conductive vias 416 can be in the circuit structure 410. The conductive vias 416 can traverse through the circuit structure 410 between the circuit active side 412 to the circuit non-active side 414. The conductive vias 416 can be exposed along the circuit active side 412 and the circuit non-active side 414.

Structure pads 418 can be along the circuit active side 412. The structure pads 418 are defined as conductive pads that provide electrical connectivity to an active surface of a device. As an example, the structure pads 418 can be made from a conductive material, such as copper, a copper alloy, gold, a gold alloy, nickel, a nickel alloy, or other alloys. The structure pads 418 can be co-planar with the circuit active side 412. The structure pads 418 can provide electrical connectivity for the active circuitry on the circuit active side 412.

A component device 420 can be on the circuit active side 412 of the circuit structure 410. The component device 420 is defined as an electrical component. As an example, the component device 420 can be a device that contains passive components, active components, or circuits formed thereof. The component device 420 can be connected to the portion of the conductive vias 416 that are exposed along the circuit active side 412, the structure pads 418, or a combination thereof.

External interconnects 422 can be connected to the circuit non-active side 414 of the circuit structure 410. The external interconnects 422 are defined as conductive connectors that provide connectivity to other devices and components that can be external to a packaging system. As an example, the external interconnects 422 can be solder balls, solder bumps, or conductive bumps.

The external interconnects 422 can be connected to the portion of the conductive vias 416 that are exposed at the circuit non-active side 414. The external interconnects 422 can connect the integrated circuit packaging system 400 to a next system level down (not shown).

The circuit structure 410 can have a through hole 424. The through hole 424 is defined as an opening or hole that traverses between one surface of a structure to an opposite surface of the structure. The through hole 424 can traverse between the circuit active side 412 and the circuit non-active side 414. The circuit structure 410 can be a single continuous structure with the through hole 424 at an inner portion of the circuit structure 410.

The conductive vias 416 can have a horizontal dimension that is smaller than the horizontal dimension of the through hole 424. The through hole 424 can be sized to fit a device, such as an integrated circuit die.

An integrated circuit device 426 can be in the through hole 424. The integrated circuit device 426 is defined as a semiconductor device. As an example, the integrated circuit device 426 can be an integrated circuit die, a thin integrated circuit die, or an ultrathin integrated circuit die. The through hole 424 can be a space between the vertical side of the circuit structure 410 parallel with and facing the vertical side of the integrated circuit device 426.

The integrated circuit device 426 can have a device active side 428 and a device non-active side 430. The device active side 428 is defined as the side of the integrated circuit device 426 having active circuitry (not shown) fabricated thereto. The device non-active side 430 is defined as the side of the integrated circuit device 426 opposite the device active side 428.

The device active side 428 can be co-planar with the circuit active side 412. The device non-active side 430 can be co-planar with the circuit non-active side 414.

The integrated circuit device 426 can have device pads 432 along the device active side 428. The device pads 432 are defined as conductive pads that provide electrical connectivity to an active surface of a device. As an example, the device pads 432 can be made from a conductive material, such as copper, a copper alloy, gold, a gold alloy, nickel, a nickel alloy, or other alloys. The device pads 432 can be co-planar with the device active side 428. The device pads 432 can provide electrical connectivity for the active circuitry on the device active side 428.

The integrated circuit packaging system 400 can include a base encapsulation 402. The base encapsulation 402 is defined as a cover a protective cover that has electric and environmental insulating properties. As an example, the base encapsulation 402 can be formed by molding an encapsulation material such as epoxy molding compound or ceramic material. As an example, the base encapsulation 402 can have characteristics of being formed by a film assisted molding or injection molding process.

The base encapsulation 402 can be over the circuit structure 410, around the integrated circuit device 426, and in the through hole 424. The base encapsulation 402 can be on the circuit active side 412 and the device active side 428. The base encapsulation 402 can cover the component device 420.

The base encapsulation 402 can have a base first side 434 and a base second side 436. The base encapsulation 402 can be in the through hole 424. The base encapsulation 402 can be in the space between the circuit structure 410 and the integrated circuit device 426. The circuit structure 410 and the integrated circuit device 426 can be exposed from the base encapsulation 402.

The circuit non-active side 414 and the device non-active side 430 can be co-planar with the base second side 436. The circuit non-active side 414, the device non-active side 430, and the base second side 436 can have the characteristics of a surface that is formed as a uniform co-planar surface. A surface formed as uniformly co-planar is defined as a surface that is formed during the same processing or manufacturing step. For example, the circuit non-active side 414, the device non-active side 430, and the base second side 436 can be formed during a single planarization step, such as grinding or polishing. As a further example, the characteristics of a surface that is formed as uniformly co-planar can include continuous and uniform grinding or polishing marks, such as grooves or scratches, across the sides or surfaces of each component or device.

The base encapsulation can have a base lateral side 438. The base lateral side 438 is defined as the vertical side of the base encapsulation 402. A structure lateral side 440 of the circuit structure 410 can be covered by the base encapsulation 402. The structure lateral side 440 is defined as the vertical side of the circuit structure 410 that is facing away from the through hole 424.

The integrated circuit packaging system 400 can include first conductive pins 442 and second conductive pins 446. The first conductive pins 442 and the second conductive pins 446 are defined as conductive structures in a protective cover that traverses between a side of an active device and a surface of the protective cover. As an example, the first conductive pins 442 and the second conductive pins 446 can be made from conductive material, such as a copper alloy, gold, a gold alloy, nickel, a nickel alloy, or other alloys. The first conductive pins 442 and the second conductive pins 446 can be in and surrounded by the base encapsulation 402.

The first conductive pins 442 can traverse between the circuit active side 412 and the base first side 434. The first conductive pins 442 can be exposed from the base encapsulation 402 at the base first side 434.

The first conductive pins 442 can have a first pin height 444. The first pin height 444 is defined as the measure of length of the first conductive pins 442 from the circuit active side 412 to the base first side 434.

The first conductive pins 442 can be connected to the circuit active side 412. For example, the first conductive pins 442 can be connected to the portion of the conductive vias 416 that are exposed at the circuit active side 412. As a further example, the first conductive pins 442 can be connected to the structure pads 418.

The second conductive pins 446 can traverse between the device active side 428 and the base first side 434. The second conductive pins 446 can be exposed from the base encapsulation 402 at the base first side 434. The exposed portion of the second conductive pins 446 can be co-planar with the base first side 434.

The second conductive pins 446 can have a second pin height 448. The second pin height 448 is defined as the measure of length of the second conductive pins 446 from the device active side 428 to the base first side 434. The second pin height 448 can be equivalent to the first pin height 444. The second pin height 448 equivalent to the first pin height 444 is defined as the distance between the base first side 434 to the circuit active side 412 for the first pin height 444 is the same as the distance between the base first side 434 and the device active side 428 for the second pin height 448.

The second conductive pins 446 can be connected to the device active side 428. For example, the second conductive pins 446 can be connected to the device pads 432.

The first conductive pins 442 and the second conductive pins 446 can have a tapered shape. A tapered shape is defined as a shape having a gradually narrowing width with one end having a greater width than an opposing end. For example, the first conductive pins 442 and the second conductive pins 446 can have a greater width at the end adjacent to the base first side 434 and narrower width at the end adjacent to the circuit active side 412 and the device active side 428, respectively.

Mount pads 404 can be on the base encapsulation 402. The mount pads 404 are defined as pads for providing electrical interface and connection to components or devices external to a packaging system. As an example, the mount pads 404 can be made from a conductive material, such as copper, a copper alloy, gold, a gold alloy, nickel, a nickel alloy, or other alloys. In a further example, the mount pads 404 can be made from at least one layer of a metallic material formed by a plating process. More specifically, the mount pads 404 can be made from a single metallic layer made from plating a single material, multiple metallic layers made from plating a single material, multiple metallic layers made from plating different materials. The mount pads 404 can be at various locations on the base encapsulation 402.

The mount pads 404 can be on the base first side 434 of the base encapsulation 402. The mount pads 404 can be connected to the portion of the first conductive pins 442 and the second conductive pins 446 at the base first side 434.

A conductive trace 406 can be on the base encapsulation 402. The conductive trace 406 is defined as a conductive interconnect that is along a surface of a cover for providing electrical connection between pads. As an example, the conductive trace 406 can be made from a conductive material, such as copper, a copper alloy, gold, a gold alloy, nickel, a nickel alloy, or other alloys.

The conductive trace 406 can be on the base first side 434 of the base encapsulation 402. The conductive trace 406 can connect one or more of the mount pads 404. The conductive trace 406 can connect the first conductive pins 442 with the second conductive pins 446. For example, the conductive trace 406 can connect between one of the mount pads 404 connected to one of the first conductive pins 442 and another one of the mount pads 404 connected to one of the second conductive pins 446.

The integrated circuit packaging system 400 can be an active substrate. The active substrate is defined as a structure, having embedded active devices, that can function as a base for mounting other devices or components. As an example, the integrated circuit packaging system 400 can components or devices mounted over the base first side. As another example, the integrated circuit packaging system 400 can be inverted and can have components or devices mounted on the circuit non-active side 414, the device non-active side 430, or a combination thereof. As a specific example, the integrated circuit packaging system 400 can be a wafer level chip scale package, which is defined as a packaging system including silicon devices, having circuitry fabricated thereon, fabricated at a wafer level.

It has been discovered that the present invention provides the integrated circuit packaging system 400 with the circuit structure 410, the integrated circuit device 426 and the base encapsulation 402 having a low package profile. The circuit non-active side 414, the device non-active side 430 and the base second side 436 having the characteristics of a uniform co-planar surface enables uniform reduction in package height for the circuit structure 410, the integrated circuit device 426 and the base encapsulation 402, thus providing integrated circuit packaging system 400 having a low profile.

It has also been discovered that the present invention provides the integrated circuit packaging system 400 with the first conductive pin 442 and the second conductive pin 446 having a low package profile. The second pin height 448 equivalent to the first pin height 444 enables uniform thickness of the portion of the base encapsulation 402 over the circuit structure 410 and the integrated circuit device 426, thus providing the integrated circuit packaging system 400 having a low package profile.

It has further been discovered that the present invention provides the integrated circuit packaging system 400 the first conductive pin 442 and the second conductive pin 446 having reliable connectivity. The first conductive pin 442 and the second conductive pin 446 having the tapered shape having a narrow end that is smaller in width than the structure pads 418 and the device pads 432 enables precise connection with the structure pads 418 and the device pads 432. The precise connection of the first conductive pin 442 and the second conductive pin 446 with the structure pads 418 and the device pads 432 reduces or eliminates the risk of shorting between the structure pads 418 with another of the structure pads 418 or the device pads 432 with another of the device pads 432, thus providing the integrated circuit packaging system having reliable connectivity.

It has yet further been discovered that the present invention provides the integrated circuit packaging system 400 with the circuit structure 410 having, improved performance and integration. The circuit structure 410 having the active circuitry along the circuit active side 412 eliminates the need for additional circuit components and connections between circuit components, thus providing the integrated circuit packaging system 400 with improved performance and integration.

It has yet further been discovered that the present invention provides the integrated circuit packaging system 400 with the circuit structure 410 having a low vertical package profile. The circuit structure 410 having the active circuitry along the circuit active side 412 eliminates the need for additional circuit components or integrated circuits, thus providing the integrated circuit packaging system 400 with a low vertical package profile.

It has yet further been discovered that the present invention provides the integrated circuit packaging system 400 with the structure lateral side 440 covered by the base encapsulation 402 having improved structural integrity. The base encapsulation 402 covering the structure lateral side 440 of the circuit structure 410 increases the bonding and contact surface area between the circuit structure 410 and the base encapsulation 402, reducing the risk of delamination and thus improving the structural integrity of the integrated circuit packaging system 400.

Referring now to FIG. 5, therein is shown a cross-sectional view of an integrated circuit packaging system 500 as exemplified by the top view of FIG. 1 along line 2-2 in a third embodiment of the present invention. The cross-sectional view depicts a circuit structure 510. The circuit structure 510 is defined as a semiconductor device. As an example, the circuit structure 510 can be an integrated circuit die, a thin integrated circuit die, or a silicon interposer. As a specific example, the circuit structure 510 can be silicon interposer made from a silicon wafer having through silicon vias (TSV).

The circuit structure 510 can have a circuit active side 512 and a circuit non-active side 514. The circuit active side 512 is defined as the side of the circuit structure 510 having active circuitry (not shown) fabricated thereto. The circuit non-active side 514 is defined as the side of the circuit structure 510 opposite the circuit active side 512.

The circuit structure 510 can include conductive vias 516. The conductive vias 516 are defined as channels or holes filled with conductive material that traverse from between one surface of a structure to an opposite surface of the structure. The conductive vias 516 can be filled with a conductive material. For example, the conductive vias can be filled with conductive materials such as copper, a copper alloy, gold, a gold alloy, nickel, a nickel alloy, or other alloys.

The conductive vias 516 can be in the circuit structure 510. The conductive vias 516 can traverse through the circuit structure 510 from the circuit active side 512 to the circuit non-active side 514. The conductive vias 516 can be exposed along the circuit active side 512 and the circuit non-active side 514.

Structure pads 518 can be along the circuit active side 512. The structure pads 518 are defined as conductive pads that provide electrical connectivity to an active surface of a device. As an example, the structure pads 518 can be made from a conductive material, such as copper, a copper alloy, gold, a gold alloy, nickel, a nickel alloy, or other alloys. The structure pads 518 can be co-planar with the circuit active side 512. The structure pads 518 can provide electrical connectivity for the active circuitry on the circuit active side 512.

A component device 520 can be on the circuit active side 512 of the circuit structure 510. The component device 520 is defined as an electrical component. As an example, the component device 520 can be a device that contains passive components, active components, or circuits formed from the combination thereof. The component device 520 can be connected to the portion of the conductive vias 516 that are exposed along the circuit active side 512, the structure pads 518, or a combination thereof.

External interconnects 522 can be connected to the circuit non-active side 514. The external interconnects 522 are defined as conductive connectors that provide connectivity to other devices and components external to a packaging system. As an example, the external interconnects 522 can be solder balls, solder bumps, or conductive bumps.

The external interconnects 522 can be connected to the portion of the conductive vias 516 that are exposed at the circuit non-active side 514. The external interconnects 522 can connect the integrated circuit packaging system 500 to a next system level down (not shown).

The circuit structure 510 can have a through hole 524. The through hole 524 is defined as an opening or hole that traverses between one surface of a structure to an opposite surface of the structure. The through hole 524 can traverse between the circuit active side 512 and the circuit non-active side 514. The circuit structure 510 can be a single continuous structure with the through hole 524 at an inner portion of the circuit structure 510.

The conductive vias 516 can have a horizontal dimension that is smaller than the horizontal dimension of the through hole 524. The through hole 524 can be sized to fit a device, such as an integrated circuit die.

An integrated circuit device 526 can be in the through hole 524. The integrated circuit device 526 is defined as a semiconductor device. As an example, the integrated circuit device 526 can be an integrated circuit die, a thin integrated circuit die, or an ultrathin integrated circuit die. The through hole 524 can be a space between the vertical side of the circuit structure 510 parallel with and facing the vertical side of the integrated circuit device 526.

The integrated circuit device 526 can have a device active side 528 and a device non-active side 530. The device active side 528 is defined as the side of the integrated circuit device 526 having active circuitry (not shown) fabricated thereon. The device non-active side 530 is defined as the side of the integrated circuit device 526 opposite the device active side 528.

The device active side 528 can be co-planar with the circuit active side 512. The device non-active side 530 can be co-planar with the circuit non-active side 514.

The integrated circuit device 526 can have device pads 532 along the device active side 528. The device pads 532 are defined as conductive pads that provide electrical connectivity to an active surface of a device. As an example, the device pads 532 can be made from a conductive material, such as copper, a copper alloy, gold, a gold alloy, nickel, a nickel alloy, or other alloys. The device pads 532 can be co-planar with the device active side 528. The device pads 532 can provide electrical connectivity for the active circuitry on the device active side 528.

The integrated circuit packaging system 500 can include a base encapsulation 502. The base encapsulation 502 is defined as a cover a protective cover that has electric and environmental insulating properties. As an example, the base encapsulation 502 can be formed by molding an encapsulation material such as epoxy molding compound or ceramic material. As an example, the base encapsulation 502 can have characteristics of being formed by a film assisted molding or injection molding process.

The base encapsulation 502 can be over the circuit structure 510, around the integrated circuit device 526, and in the through hole 524. The base encapsulation 502 can be on the circuit active side 512 and the device active side 528. The base encapsulation 502 can cover the component device 520.

The base encapsulation 502 can have a base first side 534 and a base second side 536. The base encapsulation 502 can be in the through hole 524. The base encapsulation 502 can be in the space between the circuit structure 510 and the integrated circuit device 526. The circuit structure 510 and the integrated circuit device 526 can be exposed from the base encapsulation 502.

The circuit non-active side 514 and the device non-active side 530 can be co-planar with the base second side 536. The circuit non-active side 514, the device non-active side 530, and the base second side 536 can have the characteristics of a surface that is formed as a uniform co-planar surface. A surface formed as uniformly co-planar is defined as a surface that is formed during the same processing or manufacturing step. For example, the circuit non-active side 514, the device non-active side 530, and the base second side 536 can be formed during a single planarization step, such as grinding or polishing. As a further example, the characteristics of a surface that is formed as uniformly co-planar can include continuous and uniform grinding or polishing marks, such as grooves or scratches, across the sides or surfaces of each component or device.

The base encapsulation can have a base lateral side 538. The base lateral side 538 is defined as the vertical side of the base encapsulation 502. A structure lateral side 540 of the circuit structure 510 can be covered by the base encapsulation 502. The structure lateral side 540 is defined as the vertical side of the circuit structure 510 that is facing away from the through hole 524.

The integrated circuit packaging system 500 can include first conductive pins 542 and second conductive pins 546. The first conductive pins 542 and the second conductive pins 546 are defined as conductive structures in a protective cover that traverses between a side of an active device and a surface of the protective cover. As an example, the first conductive pins 542 and the second conductive pins 546 can be made from conductive material, such as a copper alloy, gold, a gold alloy, nickel, a nickel alloy, or other alloys. The first conductive pins 542 and the second conductive pins 546 can be in and surrounded by the base encapsulation 502.

The first conductive pins 542 can traverse between the circuit active side 512 and the base first side 534. The first conductive pins 542 can be exposed from the base encapsulation 502 at the base first side 534.

The first conductive pins 542 can have a first pin height 544. The first pin height 544 is defined as the measure of length of the first conductive pins 542 from the circuit active side 512 to the base first side 534.

The first conductive pins 542 can be connected to the circuit active side 512. For example, the first conductive pins 542 can be connected to the portion of the conductive vias 516 that are exposed at the circuit active side 512. As a further example, the first conductive pins 542 can be connected to the structure pads 518.

The second conductive pins 546 can traverse between the device active side 528 and the base first side 534. The second conductive pins 546 can be exposed from the base encapsulation 502 at the base first side 534. The exposed portion of the second conductive pins 546 can be co-planar with the base first side 534.

The second conductive pins 546 can have a second pin height 548. The second pin height 548 is defined as the measure of length of the second conductive pins 546 from the device active side 528 to the base first side 534. The second pin height 548 can be equivalent to the first pin height 544. The second pin height 548 equivalent to the first pin height 544 is defined as the distance between the base first side 534 to the circuit active side 512 for the first pin height 544 is the same as the distance between the base first side 534 and the device active side 528 for the second pin height 548.

The second conductive pins 546 can be connected to the device active side 528. For example, the second conductive pins 546 can be connected to the device pads 532.

The first conductive pins 542 and the second conductive pins 546 can have a tapered shape. A tapered shape is defined as a shape having a gradually narrowing width with one end having a greater width than an opposing end. For example, the first conductive pins 542 and the second conductive pins 546 can have a greater width at the end adjacent to the base first side 534 and narrower width at the end adjacent to the circuit active side 512 and the device active side 528, respectively.

Mount pads 504 can be on the base encapsulation 502. The mount pads 504 are defined as pads for providing electrical interface and connection to components or devices external to a packaging system. As an example, the mount pads 504 can be made from a conductive material, such as copper, a copper alloy, gold, a gold alloy, nickel, a nickel alloy, or other alloys. In a further example, the mount pads 504 can be made from at least one layer of a metallic material formed by a plating process. More specifically, the mount pads 504 can be made from a single metallic layer made from plating a single material, multiple metallic layers made from plating a single material, multiple metallic layers made from plating different materials. The mount pads 504 can be at various locations on the base encapsulation 502.

The mount pads 504 can be on the base first side 534 of the base encapsulation 502. The mount pads 504 can be connected to the portion of the first conductive pins 542 and the second conductive pins 546 at the base first side 534.

A conductive trace 506 can be on the base encapsulation 502. The conductive trace 506 is defined as a conductive interconnect that is along a surface of a cover for providing electrical connection between pads. As an example, the conductive trace 506 can be made from a conductive material, such as copper, a copper alloy, gold, a gold alloy, nickel, a nickel alloy, or other alloys.

The conductive trace 506 can be on the base first side 534 of the base encapsulation 502. The conductive trace 506 can connect one or more of the mount pads 504. The conductive trace 506 can connect the first conductive pins 542 with the second conductive pins 546. For example, the conductive trace 506 can connect between one of the mount pads 504 connected to one of the first conductive pins 542 and another one of the mount pads 504 connected to one of the second conductive pins 546.

Through pins 560 can be in the base encapsulation 502. The through pins 560 are defined as conductive structures that provide direct electrical connectivity between one side of a packaging system to an opposing side of the packaging system. As an example, the through pins 560 can be made from conductive material, such as a copper alloy, gold, a gold alloy, nickel, a nickel alloy, or other alloys.

The through pins 560 can be in and surrounded by the base encapsulation 502. The through pins 560 can traverse between the base second side 536 and the base first side 534. The through pins 560 can be exposed from the base encapsulation 502 at the base second side 536 and the base first side 534. The portion of the through pins 560 exposed at the base second side 536 can be co-planar with the base second side 536. The mount pads 504 can be connected to the end of the through pins 560 at the base first side 534.

The through pins 560 can be adjacent to the circuit structure 510. The through pins 560 can be adjacent to the structure lateral side 540.

The through pins 560 can have the tapered shape. For example, the through pins 560 can have a greater width at the end adjacent to the base first side 534 and narrower width at the end exposed at the base second side 536.

The integrated circuit packaging system 500 can provide an active substrate. The active substrate is defined as a structure, having embedded active devices, that can function as a base for mounting other devices or components. As an example, the integrated circuit packaging system 500 can support components or devices mounted over the base first side. As another example, the integrated circuit packaging system 500 can be inverted and can have components or devices mounted on the circuit non-active side 514, the device non-active side 530, or a combination thereof. As a specific example, the integrated circuit packaging system 500 can be a wafer level chip scale package, which is defined as a packaging system including silicon devices, having circuitry fabricated thereon, fabricated at a wafer level.

It has been discovered that the present invention provides the integrated circuit packaging system 500 with the circuit structure 510, the integrated circuit device 526 and the base encapsulation 502 having a low package profile. The circuit non-active side 514, the device non-active side 530 and the base second side 536 having the characteristics of a uniform co-planar surface enables uniform reduction in package height for the circuit structure 510, the integrated circuit device 526 and the base encapsulation 502, thus providing an integrated circuit packaging system 500 having a low profile.

It has also been discovered that the present invention provides the integrated circuit packaging system 500 with the first conductive pin 542 and the second conductive pin 546 having a low package profile. The second pin height 548 equivalent to the first pin height 544 enables uniform thickness of the portion of the base encapsulation 502 over the circuit structure 510 and the integrated circuit device 526, thus providing the integrated circuit packaging system 500 having a low package profile.

It has further been discovered that the present invention provides the integrated circuit packaging system 500 the first conductive pin 542 and the second conductive pin 546 having reliable connectivity. The first conductive pin 542 and the second conductive pin 546 having the tapered shape having a narrow end that is smaller in width than the structure pads 518 and the device pads 532 enables precise connection with the structure pads 518 and the device pads 532. The precise connection of the first conductive pin 542 and the second conductive pin 546 with the structure pads 518 and the device pads 532 reduces or eliminates the risk of shorting between the structure pads 518 with another of the structure pads 518 or the device pads 532 with another of the device pads 532, thus providing the integrated circuit packaging system having reliable connectivity.

It has yet further been discovered that the present invention provides the integrated circuit packaging system 500 with the circuit structure 510 having, improved performance and integration. The circuit structure 510 having the active circuitry along the circuit active side 512 eliminates the need for additional circuit components and connections between circuit components, thus providing the integrated circuit packaging system 500 with improved performance and integration.

It has yet further been discovered that the present invention provides the integrated circuit packaging system 500 with the circuit structure 510 having a low vertical package profile. The circuit structure 510 having the active circuitry along the circuit active side 512 eliminates the need for additional circuit components or integrated circuits, thus providing the integrated circuit packaging system 500 with a low vertical package profile.

It has yet further been discovered that the present invention provides the integrated circuit packaging system 500 with the structure lateral side 540 covered by the base encapsulation 502 having improved structural integrity. The base encapsulation 502 covering the structure lateral side 540 of the circuit structure 510 increases the bonding and contact surface area between the circuit structure 510 and the base encapsulation 502, reducing the risk of delamination and thus improving the structural integrity of the integrated circuit packaging system 500.

It has yet further been discovered that the present invention provides the integrated circuit packaging system 500 with the through pins 560 having increased through connectivity. The through pins 560 provide additional direct through connections between system levels above and below the integrated circuit packaging system 500, thus increasing connectivity of the integrated circuit packaging system 500.

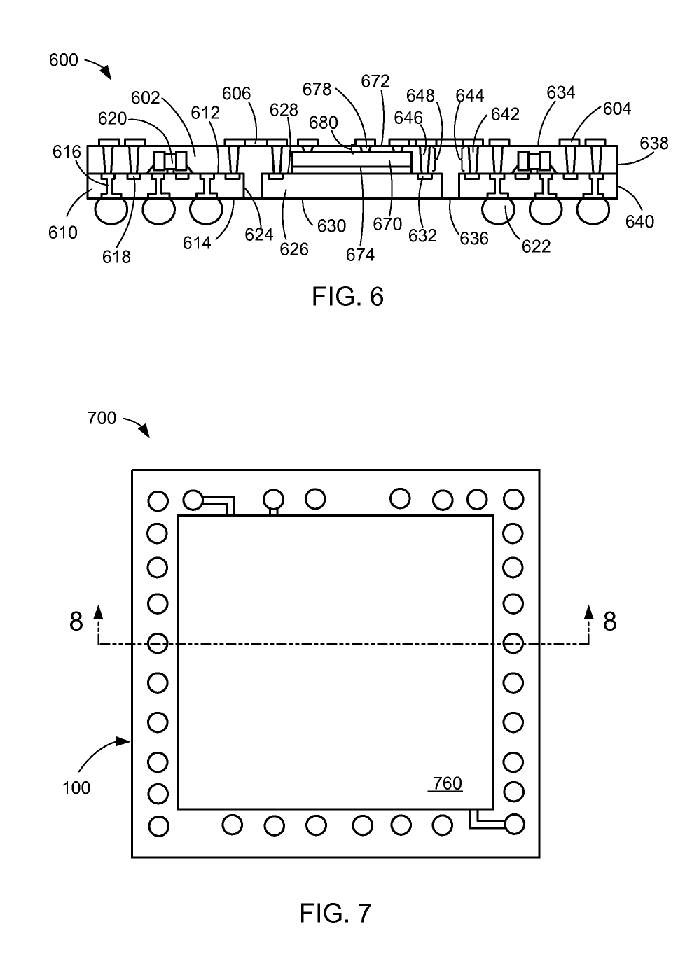

Referring now to FIG. 6, therein is shown a cross-sectional view of the integrated circuit packaging system 600 as exemplified by the top view of FIG. 1 along line 2-2 in a fourth embodiment of the present invention. The cross-sectional view depicts a circuit structure 610. The circuit structure 610 is defined as a semiconductor device. As an example, the circuit structure 610 can be an integrated circuit die, a thin integrated circuit die, or a silicon interposer. As a specific example, the circuit structure 610 can be silicon interposer made from a silicon wafer having through silicon vias (TSV).

The circuit structure 610 can have a circuit active side 612 and a circuit non-active side 614. The circuit active side 612 is defined as the side of the circuit structure 610 having active circuitry (not shown) fabricated thereto. The circuit non-active side 614 is defined as the side of the circuit structure 610 opposite the circuit active side 612.

The circuit structure 610 can include conductive vias 616. The conductive vias 616 are defined as channels or holes filled with conductive material that traverse from one surface of a structure to an opposite surface of the structure. The conductive vias 616 can be filled with a conductive material. For example, the conductive vias can be filled with conductive materials such as copper, a copper alloy, gold, a gold alloy, nickel, a nickel alloy, or other alloys.

The conductive vias 616 can be in the circuit structure 610. The conductive vias 616 can traverse through the circuit structure 610 from the circuit active side 612 to the circuit non-active side 614. The conductive vias 616 can be exposed along the circuit active side 612 and the circuit non-active side 614.

Structure pads 618 can be along the circuit active side 612. The structure pads 618 are defined as conductive pads that provide electrical connectivity to an active surface of a device. As an example, the structure pads 618 can be made from a conductive material, such as copper, a copper alloy, gold, a gold alloy, nickel, a nickel alloy, or other alloys. The structure pads 618 can be co-planar with the circuit active side 612. The structure pads 618 can provide electrical connectivity for the active circuitry on the circuit active side 612.

A component device 620 can be on the circuit active side 612. The component device 620 is defined as semiconductor component. As an example, the component device 620 can be a device that contains passive components, active components, or circuits formed from the combination thereof. The component device 620 can be connected to the portion of the conductive vias 616 that are exposed along the circuit active side 612, the structure pads 618, or a combination thereof.

External interconnects 622 can be connected to the circuit non-active side 614. The external interconnects 622 are defined as conductive connectors that provide connectivity to other devices and components external to a packaging system. As an example, the external interconnects 622 can be solder balls, solder bumps, or conductive bumps.

The external interconnects 622 can be connected to the portion of the conductive vias 616 that are exposed at the circuit non-active side 614. The external interconnects 622 can connect the integrated circuit packaging system 600 to a next system level down (not shown).

The circuit structure 610 can have a through hole 624. The through hole 624 is defined as an opening or hole that traverses between one surface of a structure to an opposite surface of the structure. The through hole 624 can traverse between the circuit active side 612 and the circuit non-active side 614. The circuit structure 610 can be a single continuous structure with the through hole 624 at an inner portion of the circuit structure 610.

The conductive vias 616 can have a horizontal dimension that is smaller than the horizontal dimension of the through hole 624. The through hole 624 can be sized to fit a device, such as an integrated circuit die.

An integrated circuit device 626 can be in the through hole 624. The integrated circuit device 626 is defined as a semiconductor device. As an example, the integrated circuit device 626 can be an integrated circuit die, a thin integrated circuit die, or an ultrathin integrated circuit die. The through hole 624 can be a space between the vertical side of the circuit structure 610 parallel with and facing the vertical side of the integrated circuit device 626.

The integrated circuit device 626 can have a device active side 628 and a device non-active side 630. The device active side 628 is defined as the side of the integrated circuit device 626 having active circuitry (not shown) fabricated thereon. The device non-active side 630 is defined as the side of the integrated circuit device 626 opposite the device active side 628.

The device active side 628 can be co-planar with the circuit active side 612. The device non-active side 630 can be co-planar with the circuit non-active side 614.

The integrated circuit device 626 can have device pads 632 along the device active side 628. The device pads 632 are defined as conductive pads that provide electrical connectivity to an active surface of a device. As an example, the device pads 632 can be made from a conductive material, such as copper, a copper alloy, gold, a gold alloy, nickel, a nickel alloy, or other alloys. The device pads 632 can be co-planar with the device active side 628. The device pads 632 can provide electrical connectivity for the active circuitry on the device active side 628.

An internal integrated circuit 670 can be mounted over the device active side 628. The internal integrated circuit 670 is defined as a semiconductor device. As an example, the internal integrated circuit 670 can be an integrated circuit die, a thin integrated circuit die, or an ultrathin integrated circuit die.

The internal integrated circuit 670 can have an internal first side 672 and an internal second side 674. The internal first side 672 is defined as the side of the internal integrated circuit 670 facing away from the integrated circuit device 626. The internal first side 672 can have active circuitry (not shown) fabricated thereto. The internal second side 674 is defined as the side of the internal integrated circuit 670 facing the integrated circuit device 626.

The integrated circuit packaging system 600 can include a base encapsulation 602. The base encapsulation 602 is defined as a cover a protective cover that has electric and environmental insulating properties. As an example, the base encapsulation 602 can be formed by molding an encapsulation material such as epoxy molding compound or ceramic material. As an example, the base encapsulation 602 can have characteristics of being formed by a film assisted molding or injection molding process.

The base encapsulation 602 can be over the circuit structure 610, around the integrated circuit device 626, and in the through hole 624. The base encapsulation 602 can be on the circuit active side 612 and the device active side 628. The base encapsulation 602 can cover the component device 620. The base encapsulation 602 can cover the internal integrated circuit 670.

The base encapsulation 602 can have a base first side 634 and a base second side 636. The base encapsulation 602 can be in the through hole 624. The base encapsulation 602 can be in the space between the circuit structure 610 and the integrated circuit device 626. The circuit structure 610 and the integrated circuit device 626 can be exposed from the base encapsulation 602.

The circuit non-active side 614 and the device non-active side 630 can be co-planar with the base second side 636. The circuit non-active side 614, the device non-active side 630, and the base second side 636 can have the characteristics of a surface that is formed as a uniform co-planar surface. A surface formed as uniformly co-planar is defined as a surface that is formed during the same processing or manufacturing step. For example, the circuit non-active side 614, the device non-active side 630, and the base second side 636 can be formed during a single planarization step, such as grinding or polishing. As a further example, the characteristics of a surface that is formed as uniformly co-planar can include continuous and uniform grinding or polishing marks, such as grooves or scratches, across the sides or surfaces of each component or device.

The base encapsulation can have a base lateral side 638. The base lateral side 638 is defined as the vertical side of the base encapsulation 602. A structure lateral side 640 of the circuit structure 610 can be exposed co-planar with the base lateral side 638. The structure lateral side 640 is defined as the vertical side of the circuit structure 610 that is facing away from the through hole 624.

The integrated circuit packaging system 600 can include first conductive pins 642 and second conductive pins 646. The first conductive pins 642 and the second conductive pins 646 are defined as conductive structures in a protective cover that traverses between a side of an active device and a surface of the protective cover. As an example, the first conductive pins 642 and the second conductive pins 646 can be made from conductive material, such as a copper alloy, gold, a gold alloy, nickel, a nickel alloy, or other alloys. The first conductive pins 642 and the second conductive pins 646 can be in and surrounded by the base encapsulation 602.

The first conductive pins 642 can traverse between the circuit active side 612 and the base first side 634. The first conductive pins 642 can be exposed from the base encapsulation 602 at the base first side 634.

The first conductive pins 642 can have a first pin height 644. The first pin height 644 is defined as the measure of length of the first conductive pins 642 from the circuit active side 612 to the base first side 634.

The first conductive pins 642 can be connected to the circuit active side 612. For example, the first conductive pins 642 can be connected to the portion of the conductive vias 616 that are exposed at the circuit active side 612. As a further example, the first conductive pins 642 can be connected to the structure pads 618.

The second conductive pins 646 can traverse between the device active side 628 and the base first side 634. The second conductive pins 646 can be exposed from the base encapsulation 602 at the base first side 634. The exposed portion of the second conductive pins 646 can be co-planar with the base first side 634.

The second conductive pins 646 can have a second pin height 648. The second pin height 648 is defined as the measure of length of the second conductive pins 646 from the device active side 628 to the base first side 634. The second pin height 648 can be equivalent to the first pin height 644. The second pin height 648 equivalent to the first pin height 644 is defined as the distance between the base first side 634 to the circuit active side 612 for the first pin height 644 is the same as the distance between the base first side 634 and the device active side 628 for the second pin height 648.

The second conductive pins 646 can be connected to the device active side 628. For example, the second conductive pins 646 can be connected to the device pads 632.

The first conductive pins 642 and the second conductive pins 646 can have a tapered shape. A tapered shape is defined as a shape having a gradually narrowing width with one end having a greater width than an opposing end. For example, the first conductive pins 642 and the second conductive pins 646 can have a greater width at the end adjacent to the base first side 634 and narrower width at the end adjacent to the circuit active side 612 and the device active side 628, respectively.

Mount pads 604 can be on the base encapsulation 602. The mount pads 604 are defined as pads for providing electrical interface and connection to components or devices external to a packaging system. As an example, the mount pads 604 can be made from a conductive material, such as copper, a copper alloy, gold, a gold alloy, nickel, a nickel alloy, or other alloys. In a further example, the mount pads 604 can be made from at least one layer of a metallic material formed by a plating process. More specifically, the mount pads 604 can be made from a single metallic layer made from plating a single material, multiple metallic layers made from plating a single material, multiple metallic layers made from plating different materials. The mount pads 604 can be at various locations on the base encapsulation 602.

The mount pads 604 can be on the base first side 634 of the base encapsulation 602. The mount pads 604 can be connected to the portion of the first conductive pins 642 and the second conductive pins 646 at the base first side 634.

A conductive trace 606 can be on the base encapsulation 602. The conductive trace 606 is defined as a conductive interconnect that is along a surface of a cover for providing electrical connection between pads. As an example, the conductive trace 606 can be made from a conductive material, such as copper, a copper alloy, gold, a gold alloy, nickel, a nickel alloy, or other alloys.

The conductive trace 606 can be on the base first side 634 of the base encapsulation 602. The conductive trace 606 can connect one or more of the mount pads 604. The conductive trace 606 can connect the first conductive pins 642 with the second conductive pins 646. For example, the conductive trace 606 can connect between one of the mount pads 604 connected to one of the first conductive pins 642 and another one of the mount pads 604 connected to one of the second conductive pins 646.

The integrated circuit packaging system 600 can include internal conductive pins 678. The internal conductive pins 678 are defined conductive structures in a protective cover that traverses between a side of an active device and a surface of the protective cover. As an example, the internal conductive pins 678 can be made from conductive material, such as a copper alloy, gold, a gold alloy, nickel, a nickel alloy, or other alloys. The internal conductive pins 678 can be in and surrounded by the base encapsulation 602.

The internal conductive pins 678 can traverse between the internal first side 672 and the base first side 634. The end of the internal conducive pins 678 at the base first side 634 can be connected to the mount pads 604. The end of the internal conductive pins 678 adjacent to the internal integrated circuit 670 can be connected to the internal first side 672.

The internal conductive pins 678 can have an internal conductive height 680. The internal conductive height 680 is defined as the measure of length of the internal conductive pins 678 from the internal first side 672 to the base first side 634. The internal conductive height 680 can be less than the first pin height 644 and the second pin height 648.

The integrated circuit packaging system 600 can provide an active substrate. The active substrate is defined as a structure, having embedded active devices, that can function as a base for mounting other devices or components. As an example, the integrated circuit packaging system 600 can support components or devices mounted over the base first side. As another example, the integrated circuit packaging system 600 can be inverted and can have components or devices mounted on the circuit non-active side 614, the device non-active side 630, or a combination thereof. As a specific example, the integrated circuit packaging system 600 can be a wafer level chip scale package, which is defined as a packaging system including silicon devices, having circuitry fabricated thereon, fabricated at a wafer level.

It has been discovered that the present invention provides the integrated circuit packaging system 600 with the circuit structure 610, the integrated circuit device 626 and the base encapsulation 602 having a low package profile. The circuit non-active side 614, the device non-active side 630 and the base second side 636 having the characteristics of a uniform co-planar surface enables uniform reduction in package height for the circuit structure 610, the integrated circuit device 626 and the base encapsulation 602, thus providing the integrated circuit packaging system 600 having a low profile.

It has also been discovered that the present invention provides the integrated circuit packaging system 600 with the first conductive pin 642 and the second conductive pin 646 having a low package profile. The second pin height 648 equivalent to the first pin height 644 enables uniform thickness of the portion of the base encapsulation 602 over the circuit structure 610 and the integrated circuit device 626, thus providing the integrated circuit packaging system 600 having a low package profile.

It has further been discovered that the present invention provides the integrated circuit packaging system 600 the first conductive pin 642 and the second conductive pin 646 having reliable connectivity. The first conductive pin 642 and the second conductive pin 646 having the tapered shape having a narrow end that is smaller in width than the structure pads 618 and the device pads 632 enables precise connection with the structure pads 618 and the device pads 632. The precise connection of the first conductive pin 642 and the second conductive pin 646 with the structure pads 618 and the device pads 632 reduces or eliminates the risk of shorting between the structure pads 618 with another of the structure pads 618 or the device pads 632 with another of the device pads 632, thus providing the integrated circuit packaging system having reliable connectivity.

It has yet further been discovered that the present invention provides the integrated circuit packaging system 600 with the circuit structure 610 having, improved performance and integration. The circuit structure 610 having the active circuitry along the circuit active side 612 eliminates the need for additional circuit components and connections between circuit components, thus providing the integrated circuit packaging system 600 with improved performance and integration.

It has yet further been discovered that the present invention provides the integrated circuit packaging system 600 with the circuit structure 610 having a low vertical package profile. The circuit structure 610 having the active circuitry along the circuit active side 612 eliminates the need for additional circuit components or integrated circuits, thus providing the integrated circuit packaging system 600 with a low vertical package profile.

It has yet further been discovered that the present invention provides the integrated circuit packaging system 600 with the internal integrated circuit 670 having increased packaging density. The internal integrated circuit 670 increases the number of circuit components having active circuitry, thus providing the integrated circuit packaging system 600 with increased packaging density.

Referring now to FIG. 7, therein is shown a top view of an integrated circuit packaging system 700 in a fifth embodiment of the present invention. The top view depicts a mountable device 760 over the integrated circuit packaging system 100. The mountable device 760 is defined as an active or passive electrical component for mounting over a packaging system. As an example, the mountable device 760 can be an integrated circuit die, a flip chip, a packaged integrated circuit, or a passive device.

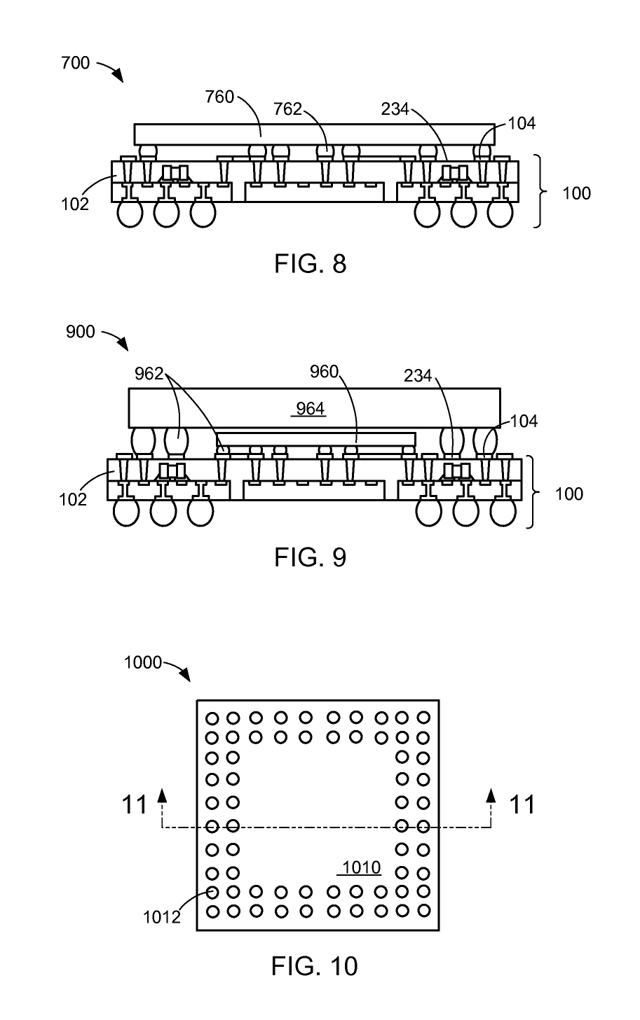

Referring now to FIG. 8, therein is shown a cross-sectional view of the integrated circuit packaging system 700 along line 8-8 of FIG. 7. The cross-sectional view depicts the mountable device 760 mounted over the integrated circuit packaging system 100. The mountable device 760 can be mounted over the base first side 234 of the base encapsulation 102.

The mountable device 760 can be connected to the integrated circuit packaging system 100 with mountable interconnects 762. The mountable interconnects 762 are defined as conductive structures that provide electrical connectivity between two devices. As an example, the mountable interconnects 762 can be solder balls, solder bumps, or conductive bumps. The mountable interconnects 762 can connect the mountable device 760 to the mount pads 104.

Referring now to FIG. 9, therein is shown a cross-sectional view of an integrated circuit packaging system 900 as exemplified by the top view along line 8-8 of FIG. 7 in a sixth embodiment of the present invention. The cross-sectional view depicts a first mountable device 960 over the integrated circuit packaging system 100. The first mountable device 960 is defined as an active or passive electrical component for mounting over a packaging system. As an example, the first mountable device 960 can be an integrated circuit die, a flip chip, a packaged integrated circuit, or a passive device. The first mountable device 960 can be mounted over the base first side 234 of the base encapsulation 102.

A second mountable device 964 can be mounted over the integrated circuit packaging system 100. The second mountable device 964 is defined as an active or passive electrical component for mounting over a packaging system. As an example, the second mountable device 964 can be an integrated circuit die, a flip chip, a packaged integrated circuit, or a passive device. The second mountable device 964 can be mounted over the base first side 234 with the first mountable device 960 in between.

The first mountable device 960 and the second mountable device 964 can be connected to the integrated circuit packaging system 100 with the mountable interconnects 962. The mountable interconnects 962 are defined as conductive structures that provide electrical connectivity between two devices. As an example, the mountable interconnects 962 can be solder balls, solder bumps, or conductive bumps. The mountable interconnects 962 can connect the first mountable device 960 and the second mountable device 964 to the mount pads 104.

Referring now to FIG. 10, therein is shown a top view of an integrated circuit packaging system 1000 in a seventh embodiment of the present invention. The top view depicts a top encapsulation 1010. The top encapsulation 1010 is defined as a cover a protective cover that has electric and environmental insulating properties. As an example, the top encapsulation 1010 can be formed by molding an encapsulation material such as epoxy molding compound or ceramic material. As a further example, the top encapsulation 1010 can have characteristics of being formed by a film assisted molding or injection molding process.

Top pads 1012 can be on the top encapsulation 1010. The top pads 1012 are defined as pads for providing electrical interface and connection to components or devices external to packaging system. As an example, the top pads 1012 can be made from a conductive material, such as copper, a copper alloy, gold, a gold alloy, nickel, a nickel alloy, or other alloys. In a further example, the top pads 1012 can be made from at least one layer of a metallic material formed by a plating process. The top pads 1012 can be along the peripheral region of the top encapsulation 1010.

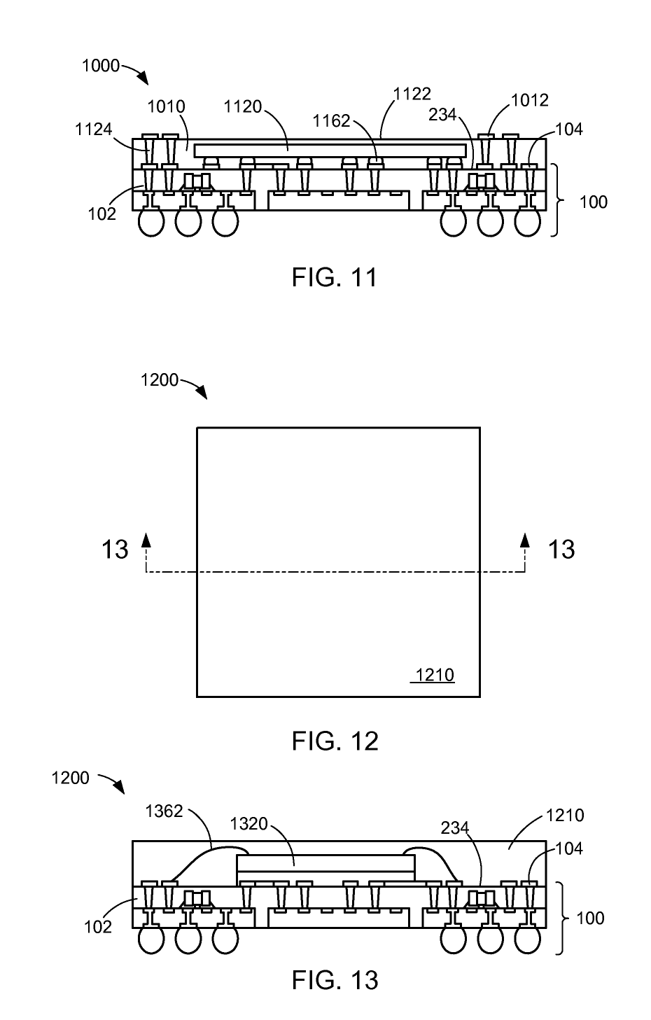

Referring now to FIG. 11, therein is shown a cross-sectional view of the integrated circuit packaging system 1000 along line 11-11 of FIG. 10. The cross-sectional view depicts a mountable integrated circuit 1120 mounted over the integrated circuit packaging system 100. The mountable integrated circuit 1120 is defined as a semiconductor device having active circuitry (not shown) fabricated thereto. As an example, the mountable integrated circuit 1120 can be an integrated circuit die, a thin integrated circuit die, an ultrathin integrated circuit die, or a flipchip die.

The mountable integrated circuit 1120 can be connected to the mount pads 104 with mountable interconnects 1162. The mountable interconnects 1162 are defined as defined as conductive structures that provide electrical connectivity between two devices. As an example, the mountable interconnects 1162 can be solder balls, solder bumps, or conductive bumps.

The top encapsulation 1010 can have an encapsulation top side 1122. The encapsulation top side 1122 is the side of the top encapsulation 1010 facing away from the integrated circuit packaging system 100. The top encapsulation 1010 can be on and over the base encapsulation 102. The top encapsulation 1010 can cover the mount pads 104, the conductive trace 106, the mountable interconnects 1162, and the mountable integrated circuit 1120.

The integrated circuit packaging system 1000 can include top conductive pins 1124. The top conductive pins 1124 are defined as conductive structures in a protective cover that traverses between one surface of a protective cover and an opposite surface of the protective cover. As an example, the top conductive pins 1124 can be made from conductive material, such as a copper alloy, gold, a gold alloy, nickel, a nickel alloy, or other alloys. The top conductive pins 1124 can be in and surrounded by the top encapsulation 1010.

The top conductive pins 1124 can traverse between the encapsulation top side 1122 and the base first side 234 of the base encapsulation 102. The end of the top conductive pins 1124 at the base first side 234 can be connected to the mount pads 102. The end of the top conductive pins 1124 at the encapsulation top side 1122 can be connected to the top pads 1012.

The top conductive pins 1124 can have the tapered shape. For example, the top conductive pins 1124 can have a greater width at the end connected to the top pads 1012 and narrower width at the end connected to the mount pads 104.

Referring now to FIG. 12, therein is shown a top view of an integrated circuit packaging system 1200 in an eighth embodiment of the present invention. The top view depicts a top encapsulation 1210. The top encapsulation 1210 is defined as a cover a protective cover that has electric and environmental insulating properties. As an example, the top encapsulation 1210 can be formed by molding an encapsulation material such as epoxy molding compound or ceramic material. As a further example, the top encapsulation 1210 can have characteristics of being formed by a film assisted molding or injection molding process.

Referring now to FIG. 13, therein is shown a cross-sectional view of the integrated circuit packaging system 1200 along line 13-13 of FIG. 12. The cross-sectional view depicts a mountable integrated circuit 1320 mounted over the integrated circuit packaging system 100. The mountable integrated circuit 1320 is defined as a semiconductor device having active circuitry (not shown) fabricated thereto. As an example, the mountable integrated circuit 1320 can be an integrated circuit die, a thin integrated circuit die, an ultrathin integrated circuit die, or a wirebond die.

The mountable integrated circuit 1320 can be connected to the mount pads 104 with mountable interconnects 1362. The mountable interconnects 1362 are defined as defined as conductive structures that provide electrical connectivity between two devices. As an example, the mountable interconnects 1362 can be bond wires or ribbon bond wires.

The top encapsulation 1210 can be on and over the base encapsulation 102. The top encapsulation 1210 can cover the mount pads 104, the conductive trace 106, the base first side 234, the mountable interconnects 1362, and the mountable integrated circuit 1320.

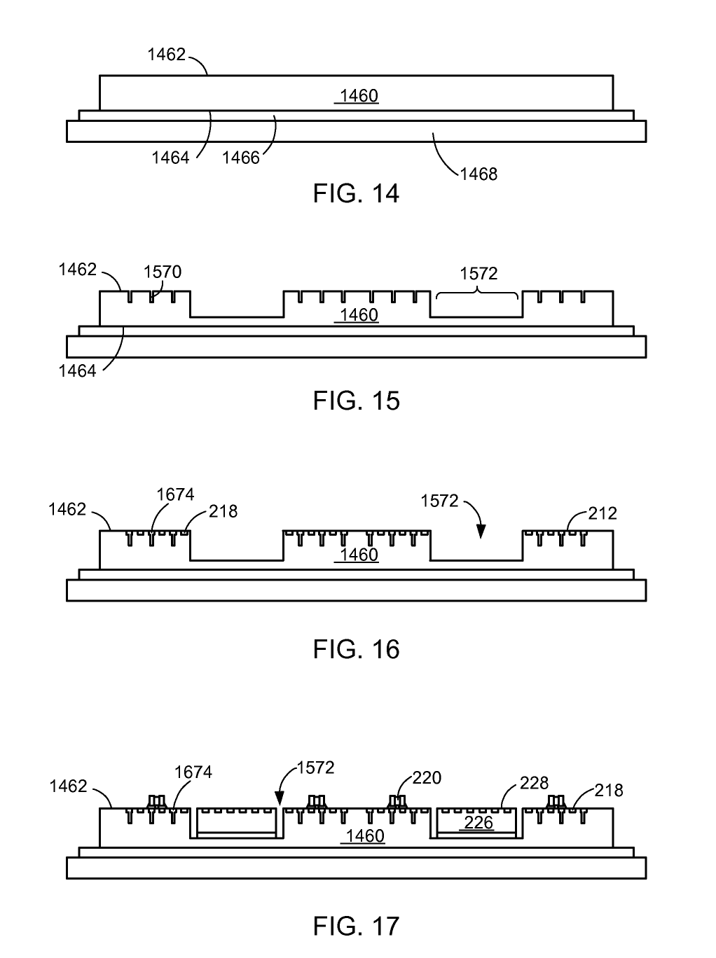

Referring now to FIG. 14, therein is shown a cross-sectional view of a wafer 1460. The wafer 1460 is defined as a structure made of a semiconductor material for fabricating integrated circuit devices and components. The wafer 1460 can have a wafer first side 1462 and a wafer second side 1464.

The wafer 1460 can be mounted to a wafer support 1468 with a wafer adhesive 1466. The wafer support 1468 is defined as a structure for providing physical support for the wafer 1460 during processing. For example, the wafer support 1468 can be a rigid material capable of withstanding high processing temperatures. As a further example, the wafer support 1468 can be a material that is resistant to chemical etching processes. As a specific example, the wafer support 1468 can be made of materials such as glass, metal, or silicon.

The wafer adhesive 1466 is defined as a material used to fix the wafer 1460 to the wafer support 1468 during processing. For example, the wafer adhesive 1466 can be a bonding material capable of withstanding high processing temperatures and resistant to chemical etching processes. The wafer adhesive 1466 can attach the wafer second side 1464 with the wafer support 1468.

Referring now to FIG. 15, therein is shown a cross-sectional view of the structure of FIG. 14 in forming cavities 1572. The cavities 1572 can be formed along the wafer first side 1462 of the wafer 1460. The cavities 1572 do not traverse to the wafer second side 1464 of the wafer 1460. The cavities 1572 can have a depth and width sized to accommodate an integrated circuit die.

Channels 1570 can be formed along the wafer first side 1462. The channels are defined as spaces or holes in a surface that can be filled with a conductive material. The channels 1570 can have a depth and width that is less than the depth and the width of the cavities 1572. The channels 1570 do not traverse to the wafer second side 1464. Forming the channels 1570 and the cavities 1572 can form a portion of the circuit structure 210 of FIG. 2.

The channels 1570 and the cavities 1572 can be formed in a number of different ways. For example, the channels 1570 and the cavities 1572 can be formed by an etching process, such as chemical etching or dry etching.

Referring now to FIG. 16, therein is shown a cross-sectional view of the structure of FIG. 15 in forming filled channels 1674. The filled channels 1674 are defined as holes or channels in a surface that are filled with conductive material. The filled channels 1674 can be exposed from at the wafer first side 1462 of the wafer 1460.

The filled channels 1674 can be formed by filling the channels 1570 of FIG. 15 with conductive material. For example, the filled channels 1674 can be made from conductive material, such as copper, a copper alloy, gold, a gold alloy, nickel, a nickel alloy, or other alloys.

The filled channels 1674 and the structure pads 218 can be formed in the same step or by the same or similar methods. The filled channels 1674 and the structure pads 218 can be formed in a number of different ways. For example, the filled channels 1674 can be formed by methods such as electroplating, chemical vapor deposition, sputtering, or physical vapor deposition. The structure pads 218 can be formed along the wafer first side 1462 by the same or similar method used to form the filled channels 1674.

Active circuitry (not shown) can be formed along the wafer first side 1462. The active circuitry can be formed in the same step, a previous step, or a step subsequent to forming the filled channels 1674.

Forming the filled channels 1674, the structure pads 218, and the active circuitry at the wafer first side 1462 can form the circuit active side 212. The cavities 1572 can be at the circuit active side 212.

Referring now to FIG. 17, therein is shown a cross-sectional view of the structure of FIG. 16 in mounting the integrated circuit device 226. The integrated circuit device 226 can be mounted in the cavities 1572 of the wafer 1460. The integrated circuit device 226 can be mounted in the cavities 1572 with the device active side 228 co-planar with the wafer first side 1462.

The component device 220 can be mounted on the wafer first side 1462. The component device 220 can be connected to the portion of the filled channels 1674 that are exposed along the wafer first side 1462, the structure pads 218, or a combination thereof.

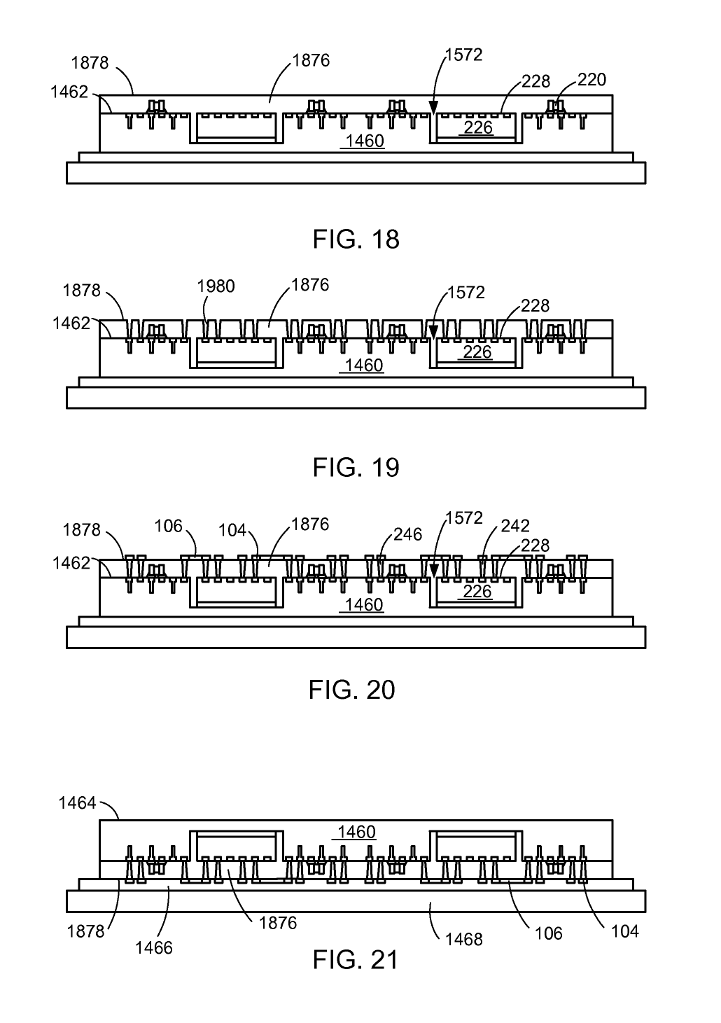

Referring now to FIG. 18, therein is shown a cross-sectional view of the structure of FIG. 17 in forming a wafer encapsulation 1876. The wafer encapsulation 1876 is defined as a cover a protective cover that has electric and environmental insulating properties. As an example, the wafer encapsulation 1876 can be a molded encapsulation material such as epoxy molding compound or ceramic material. The wafer encapsulation 1876 can have an encapsulation top side 1878. The encapsulation top side 1878 is defined as the surface of the wafer encapsulation 1876 facing away from the wafer 1460.

The wafer encapsulation 1876 can be over the wafer first side 1462 of the wafer 1460 and the device active side 228 of the integrated circuit device 226. The wafer encapsulation 1876 can cover the component device 220 and fill the cavities 1572.

The wafer encapsulation 1876 can be formed in a number of different ways. For example, the wafer encapsulation 1876 can be formed by film assisted molding, spin coating, or injection molding.

Referring now to FIG. 19, therein is shown a cross-sectional view of the structure of FIG. 18 in forming encapsulation channels 1980. The encapsulation channels 1980 are defined as channels in a surface of an encapsulation that can be filled with a conductive material.

The encapsulation channels 1980 can be formed along the encapsulation top side 1878. The encapsulation channels 1980 can traverse from the encapsulation top side 1878 to the wafer first side 1462. Portions of the wafer first side 1462 can be exposed in the encapsulation channels 1980.

The encapsulation channels 1980 can traverse from the encapsulation top side 1878 to the device active side 228. Portions of the device active side 228 can be exposed in the encapsulation channels 1980.

The encapsulation channels 1980 can be formed in a number of different ways. For example, the encapsulation channels 1980 can be formed by ablation or etching techniques, such as laser ablation or chemical etching.

Referring now to FIG. 20, therein is shown a cross-sectional view of the structure of FIG. 19 in forming the first conductive pins 242 and the second conductive pins 246. The first conductive pins 242 and the second conductive pins 246 can be formed by filling the encapsulation channels 1980 of FIG. 19 with conductive material.

The first conductive pins 242 and the second conductive pins 246 can be formed by a number of different methods. For example, the encapsulation channels 1980 can be filled with conductive material by a plating or deposition process, such as chemical vapor deposition or physical vapor deposition, or through a sputtering process. The mount pads 104 and the conductive trace 106 can be formed along the encapsulation top side 1878 of the wafer encapsulation 1876 by the same or similar methods used to form the first conductive pins 242 and the second conductive pins 246.

Referring now to FIG. 21, therein is shown a cross-sectional view of the structure of FIG. 20 in a singulation tape mounting process. The wafer second side 1464 of the wafer 1460 can be exposed by flipping of inverting the structure of FIG. 20 on to another one of the wafer support 1468. Another one of the wafer adhesive 1466 can be applied between the encapsulation top side 1878 of the wafer encapsulation 1876 to protect the mount pads 104 and the conductive trace 106 during further handling and processing.

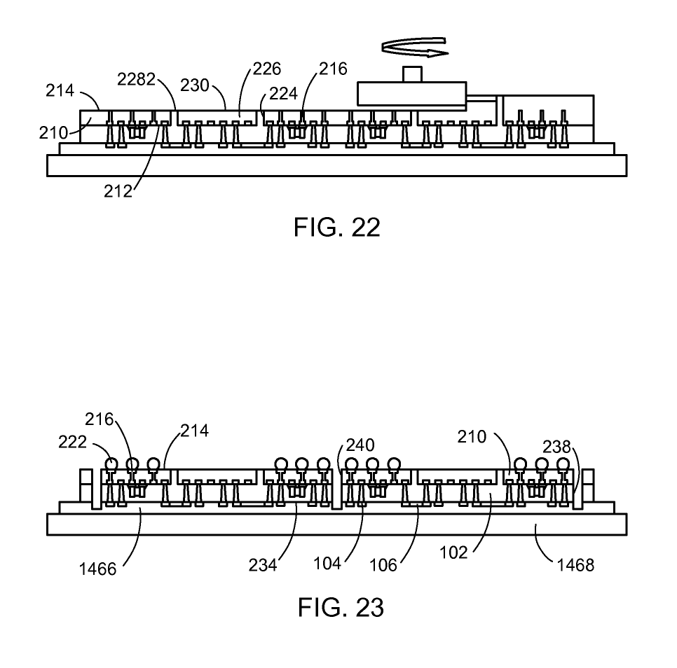

Referring now to FIG. 22, therein is shown a cross-sectional view of the structure of FIG. 21 in a wafer thinning process. The circuit structure 210 can be formed by removing a portion of the wafer 1460 of FIG. 21 along the wafer second side 1464 of FIG. 21. Removing a portion of the wafer 1460 can include removing a portion of the circuit structure 210.

Removing the portion of the wafer 1460 and the circuit structure 210 along the side of the circuit structure 210 facing away from the circuit active side 212 can form the circuit non-active side 214 of the circuit structure 210 and the device non-active side 230 of the integrated circuit device 226. Removing the portion of the wafer 1460 can form the through hole 224 of the circuit structure 210.

Removing the portion of the wafer 1460 can form an encapsulation bottom side 2282 of the wafer encapsulation 1876. The circuit non-active side 214 can be co-planar with the device non-active side 230 and the encapsulation bottom side 2282. The circuit non-active side 214 and the device non-active side 230 can be exposed from the wafer encapsulation 1876.

Removing the portion of the wafer 1460 can expose the filled channels 1674 of FIG. 21 to form the conductive vias 216. The portion of the conductive vias 216 exposed from the circuit structure 210 can be co-planar with the circuit non-active side 214.

The portion of the wafer 1460 along the wafer second side 1464 can be removed by a number of different methods. For example, the portion of the wafer 1460 can be removed by methods, such as cutting or grinding.

After removing the portion of the wafer 1460, the circuit structure 210 and the integrated circuit device 226 can be post processed. Post processing can include back-side forming insulation (not shown), circuit patterning (not shown), or under bump metallization formation (not shown) on the circuit non-active side 214 and the device non-active side. The under bump metallization can be optional.

Referring now to FIG. 23, therein is shown a cross-sectional view of the structure of FIG. 22 in a package singulation process for forming the integrated circuit packaging system 100 of FIG. 1. The external interconnects 222 can be connected to the portion of the conductive vias 216 exposed at the circuit non-active side 214.

The wafer 1460 of FIG. 21 can be singulated to form the base lateral side 238 of the base encapsulation 102 and the structure lateral side 240 of the circuit structure 210. The wafer 1460 can be singulated in a number of different ways. For example, the wafer 1460 can be singulated by physical methods, such as sawing or laser cutting, or chemical methods, such as chemical etching.

The wafer support 1468 and the wafer adhesive 1466 can be removed to form the integrated circuit packaging system 100. Removing the wafer support 1468 and the wafer adhesive 1466 can expose the base first side 234, the conductive trace 106, and the mount pads 104.

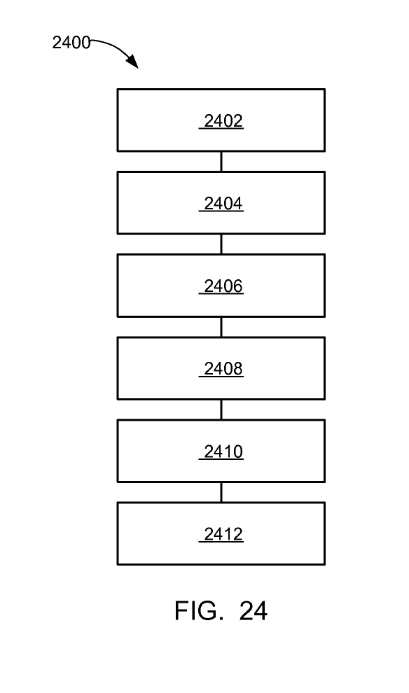

Referring now to FIG. 24, therein is shown a flow chart of a method 2400 of manufacture of the integrated circuit packaging system 100 in a further embodiment of the present invention. The method 2400 includes: forming a circuit structure having a circuit active side and a cavity from the circuit active side in a block 2402; mounting an integrated circuit device in the cavity in a block 2404; forming a base encapsulation, having a base first side facing away from the circuit active side, on the circuit active side, around the integrated circuit device, and in the cavity in a block 2406; forming a first conductive pin, having a first pin height, in the base encapsulation and traversing from the circuit active side to the base first side in a block 2408; forming a second conductive pin, having a second pin height equivalent to the first pin height, in the base encapsulation and traversing from the integrated circuit device to the base first side in a block 2410; and removing a portion of the circuit structure to form a circuit non-active side and expose the integrated circuit device and a base second side, the base second side opposite the base first side in a block 2412.

Thus, it has been discovered that the integrated circuit packaging system of the present invention furnishes important and heretofore unknown and unavailable solutions, capabilities, and functional aspects for interconnects. The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems/fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
forming a circuit structure having a circuit active side and a cavity from the circuit active side;
mounting an integrated circuit device in the cavity;
forming a base encapsulation, having a base first side facing away from the circuit active side, on the circuit active side, around the integrated circuit device, and in the cavity;
forming a first conductive pin, having a first pin height, in the base encapsulation and traversing from the circuit active side to the base first side;
forming a second conductive pin, having a second pin height equivalent to the first pin height, in the base encapsulation and traversing from the integrated circuit device to the base first side; and
removing a portion of the circuit structure to form a circuit non-active side and expose the integrated circuit device and a base second side, the base second side opposite the base first side.

2. The method as claimed in claim 1 further comprising forming a through pin, adjacent to the circuit structure, in the base encapsulation and traversing from the base first side to the base second side.

3. The method as claimed in claim 1 wherein forming the circuit structure includes forming a conductive via, in the circuit structure, traversing from the circuit active side to the circuit non-active side.

4. The method as claimed in claim 1 wherein removing the portion of the circuit structure includes forming a through hole traversing from the circuit active side and the circuit non-active side.

5. The method as claimed in claim 1 further comprising mounting a mountable device on the base first side of the base encapsulation.

6. A method of manufacture of an integrated circuit packaging system comprising:
forming a circuit structure having a circuit active side and a cavity from the circuit active side;
mounting an integrated circuit device, having a device active side, in the cavity;
forming a base encapsulation, having a base first side facing away from the circuit active side and a base second side opposite the base first side, on the circuit active side, around the integrated circuit device, and in the cavity;
forming a first conductive pin, having a first pin height, in the base encapsulation traversing from the circuit active side to and co-planar with the base first side;
forming a second conductive pin, having a second pin height equivalent to the first pin height, in the base encapsulation traversing from the device active side to and co-planar with the base first side; and
removing a portion of the circuit structure to form a circuit non-active side, a device non-active side of the integrated circuit device, and expose a base second side.

7. The method as claimed in claim 6 wherein forming the first conductive pin includes connecting the first conductive pin with a conductive via in the circuit structure.

8. The method as claimed in claim 6 further comprising:
mounting an internal integrated circuit on the device active side of the integrated circuit device; and
wherein forming the base encapsulation includes covering the internal integrated circuit.

9. The method as claimed in claim 6 further comprising mounting a component device on the circuit active side of the circuit structure.

10. The method as claimed in claim 6 wherein the circuit non-active side and the device non-active side are exposed from the base encapsulation and co-planar with the base second side.

11. An integrated circuit packaging system comprising:
a circuit structure having a through hole, a circuit active side, and a circuit non-active side with the through hole traversing from the circuit active side to the circuit non-active side;
an integrated circuit device in the through hole;
a base encapsulation, having a base first side facing away from the circuit active side and a base second side opposite the base first side, on the circuit active side, around the integrated circuit device, and in the through hole;
a first conductive pin, having a first pin height, in the base encapsulation and traversing from the circuit active side to the base first side; and
a second conductive pin, having a second pin height equivalent to the first pin height, in the base encapsulation and traversing from the integrated circuit device to the base first side.

12. The system as claimed in claim 11 further comprising a through pin, adjacent to the circuit structure, in the base encapsulation and traversing from the base first side to the base second side.

13. The system as claimed in claim 11 further comprising a conductive via in the circuit structure and traversing from the circuit active side to the circuit non-active side.

14. The system as claimed in claim 11 further comprising a conductive trace connecting the first conductive pin and the second conductive pin.

15. The system as claimed in claim 11 further comprising a mountable device on the base first side of the base encapsulation.

16. The system as claimed in claim 11 wherein:
the integrated circuit device includes a device active side and a device non-active side;
and the second conductive pin traverses from the device active side to the base first side.

17. The system as claimed in claim 16 wherein the first conductive pin is connected with a conductive via in the circuit structure.

18. The system as claimed in claim 16 further comprising:
an internal integrated circuit on the device active side of the integrated circuit device; and
wherein the base encapsulation covers the internal integrated circuit.

19. The system as claimed in claim 16 further comprising a component device on the circuit active side of the circuit structure.

20. The system as claimed in claim 16 wherein the circuit non-active side and the device non-active side are exposed from the base encapsulation and co-planar with the base second side.
